(19) United States
(12) Patent Application Publication
(10) Pub. No.: US 2024/0321552 A1
(43) Pub. Date: Sep. 26, 2024

(54) Impedance Matching Network and Control Method

(71) Applicant: Tokyo Electron Limited, Tokyo (JP)

(72) Inventors: John Carroll, Austin, TX (US); Jianping Zhao, Austin, TX (US)

(21) Appl. No.: 18/187,558

(22) Filed: Mar. 21, 2023

(51) Int. Cl. H01J 37/32; H03H 7/38

(52) U.S. Cl. CPC H01J 37/32183; H03H 7/38; H01J 2237/327

(57) ABSTRACT

A matching circuit for a plasma tool including an impedance matching network configured to be coupled between a power supply and a plasma chamber, the plasma chamber being configured to operate a plasma in a predetermined frequency range, the power supply being configured to provide power for the plasma chamber, the impedance matching network including a first pi-network and a second pi-network in series coupled between an input of the plasma chamber and an output of the power supply, and the impedance matching network being configured such that, during operation of the plasma chamber in the predetermined frequency range, an impedance of the impedance matching network and the plasma chamber equals an impedance of the power supply.

### TECHNICAL FIELD

The present invention relates generally to an impedance matching network coupled between a power source and a plasma chamber of a plasma processing system.

### BACKGROUND

Semiconductor fabrication processes may involve various manufacturing techniques including formation, patterning and removing a number of layers over a substrate. Plasma processes are commonly used in various steps of semiconductor fabrication processes. For example, reactive ion etching (RIE), plasma-enhanced CVD (PECVD) and plasma-enhanced atomic layer deposition (PEALD) are common process steps in the fabrication of semiconductor devices.

The plasma used in the semiconductor fabrication processes is commonly generated in a plasma chamber. A gas source supplies a process gas to the plasma chamber. A low frequency or high frequency radio frequency (RF) power source is coupled to the plasma chamber through an impedance matching network. The RF power source drives current through the gas in the plasma chamber. In response to the current through gas, the atoms of the gas break down into freely moving charged particles that form the plasma. The plasma can be used to perform various semiconductor fabrication processes such as deposition processes, etching processes and the like.

An impedance matching network is needed for efficiently delivering power from the RF power source to an antenna of the plasma chamber. More particularly, the impedance matching network is employed to eliminate the reflected power at the power source/antenna interface so that the maximum power output from the power source is delivered into the plasma chamber. The impedance matching network is either a high frequency impedance matching network or a low frequency impedance matching network. The high frequency impedance matching network is an L-shaped matching network consisting of only two capacitors. A shunt capacitor is coupled between the output of the power source and ground. A series capacitor is coupled between the output of the power source and the input of the plasma chamber. Both the shunt capacitor and the series capacitor may be implemented as adjustable capacitors. The low frequency impedance matching network is similar to the high frequency impedance matching network described above, except that the low frequency impedance matching network also comprises a series inductor coupled between the series capacitor and the input of the plasma chamber. The series capacitor may be implemented as an adjustable inductor.

As the plasma processes in the semiconductor industry further advance, the plasma may operate in a wider frequency range. The existing matching networks are not able to provide impedance matching over such a wide frequency range. Thus, there is a need to improve the impedance matching network so as to meet the requirements of the ever-changing plasma processes.

### SUMMARY

In accordance with an embodiment, a matching circuit for a plasma tool comprises an impedance matching network configured to be coupled between a power supply and a plasma chamber, the plasma chamber being configured to operate a plasma in a predetermined frequency range, the power supply being configured to provide power for the plasma chamber, the impedance matching network comprising a first pi-network and a second pi-network in series coupled between an input of the plasma chamber and an output of the power supply, and the impedance matching network being configured such that, during operation of the plasma chamber in the predetermined frequency range, an impedance of the impedance matching network and the plasma chamber equals an impedance of the power supply.

In accordance with another embodiment, a method comprises providing power from a power supply to a plasma chamber, wherein an impedance matching network is coupled between an output of the power supply and an input of the plasma chamber, the impedance matching network comprising a first pi-network and a second pi-network connected in series, and wherein the impedance matching network comprises a combined total of six adjustable capacitive elements and adjustable inductive elements, configuring the plasma chamber to operate at a first frequency within a predetermined frequency range, the predetermined frequency range extending from a second frequency to a third frequency, the third frequency being higher than the second frequency and based on the first frequency, adjusting the impedance matching network such that an impedance of the impedance matching network and the plasma chamber equals an impedance of the power supply.

In accordance with yet another embodiment, a system comprises a plasma chamber coupled to a power source and an impedance matching network coupled between an output of the power source and an input of the plasma chamber, wherein the impedance matching network is configured such that, in a predetermined frequency range, an impedance of the impedance matching network and the plasma chamber is equal to an impedance of the power source, wherein the impedance matching network comprises a first pi-network comprising a first adjustable capacitor, a second adjustable capacitor, and a first adjustable inductor, and a third adjustable capacitor coupled in parallel with the first adjustable inductor.

The foregoing has outlined rather broadly the features and technical advantages of the present disclosure in order that the detailed description of the disclosure that follows may be better understood. Additional features and advantages of the disclosure will be described herein, which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a block diagram of a plasma processing system in accordance with various embodiments of the present disclosure;

FIG. 2 illustrates a schematic of the plasma processing system shown in FIG. 1, in accordance with various embodiments of the present disclosure;

FIG. 3 illustrates an implementation of the impedance matching network shown in FIGS. 1-2, in accordance with various embodiments of the present disclosure;

FIG. 4 illustrates a flow chart of a method used for varying the values of the adjustable elements of the impedance matching network shown in FIGS. 1-3, in accordance with various embodiments of the present disclosure;

FIG. 5 illustrates an implementation of the adjustable capacitor of the impedance matching network shown in FIGS. 1-3, in accordance with various embodiments of the present disclosure;

FIG. 6 illustrates a first implementation of the adjustable inductor of the impedance matching network shown in FIGS. 1-3, in accordance with various embodiments of the present disclosure;

FIG. 7 illustrates a second implementation of the adjustable inductor of the impedance matching network shown in FIGS. 1-3, in accordance with various embodiments of the present disclosure; and

FIG. 8 illustrates a flow chart of a method for controlling the impedance matching network shown in FIGS. 1-3 in accordance with various embodiments of the present disclosure.

Corresponding numerals and symbols in the different figures generally refer to corresponding parts unless otherwise indicated. The figures are drawn to clearly illustrate the relevant aspects of the various embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The present disclosure will be described with respect to preferred embodiments in a specific context, namely an apparatus and method for broadband impedance matching between a medium frequency to high frequency radio frequency (RF) power source and an antenna of a plasma chamber. The apparatus and method allows for impedance matching over a wide frequency range. In addition, the apparatus and method allows for the isolation of the RF power source from frequencies that may be present at the plasma chamber (also referred to subsequently as the load) that are above the frequency range that the broadband impedance matching network is designed for. Hereinafter, various embodiments will be explained in detail with reference to the accompanying drawings.

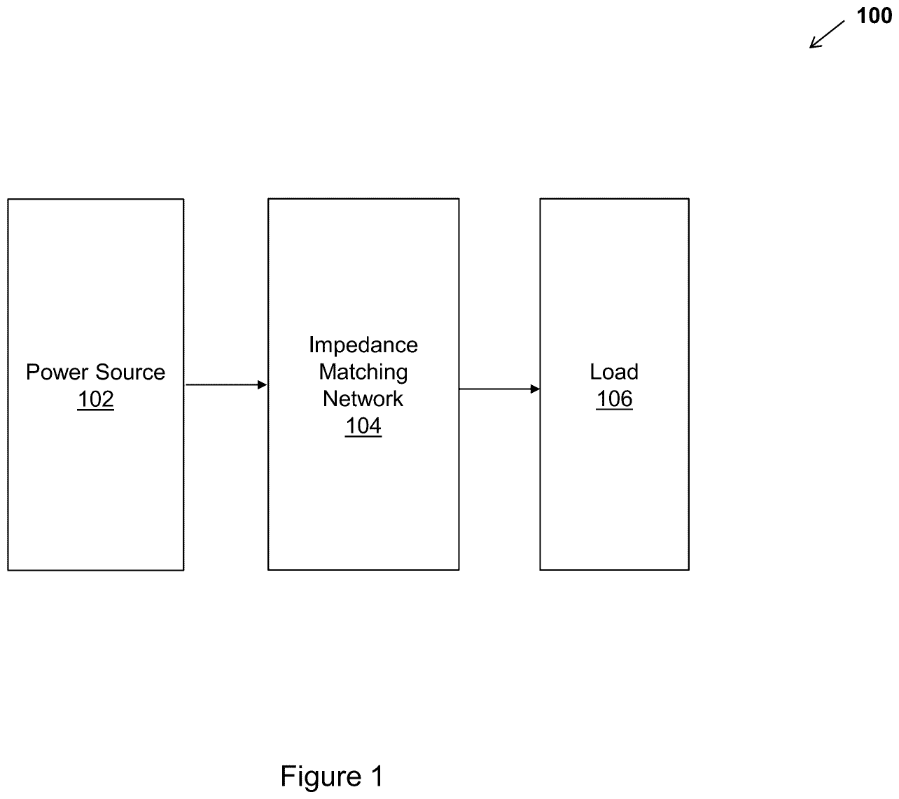

FIG. 1 illustrates a block diagram of a plasma processing system in accordance with various embodiments of the present disclosure. The plasma processing system 100 comprises a power source 102, an impedance matching network 104 and a load 106. As shown in FIG. 1, the output of the power source 102 is coupled to the input of the load 106 through the impedance matching network 104.

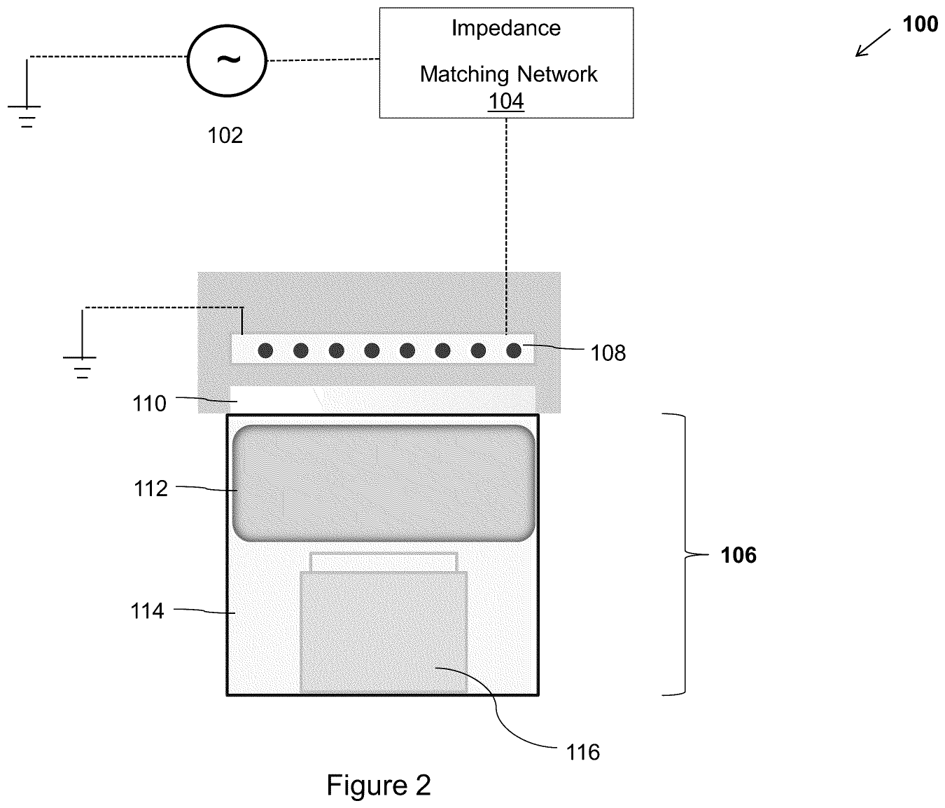

FIG. 2 shows a schematic of the plasma processing system 100. The plasma processing system 100 may be used to generate plasma to assist in a plasma process. The plasma process may be carried out in a plasma processing chamber 114 such as a medium frequency ((MF) 300 kHz-3 MHz) or high frequency ((HF) 3 MHz-30 MHz) plasma chamber. In the plasma processing system 100, the load 106 is the plasma chamber. The plasma process may include an etch process such as a Reactive Ion Etch (RIE) process, an Atomic Layer Etch (ALE) process or the like. In alternative embodiments, the plasma process may include a deposition process such as a Plasma-Enhanced Physical Vapor Deposition (PVD) process, a Plasma-Enhanced Chemical Vapor Deposition (CVD) process, an Atomic Layer Deposition (ALD) process or the like.

The power source 102 is employed to provide RF power to the load 106. The RF power is used to sustain the plasma. The source impedance of the power source 102 may be predetermined (e.g., 50 ohm). In order to maximize RF power transmission to the load 106, and to prevent the RF power from being reflected back to the power source 102, the impedance matching network 104 is employed to match the load to the source impedance (e.g., 50 ohm) of power source 102 over the wide operating frequency range of the plasma chamber. Throughout the description, the power source 102 may be alternatively referred to as a power supply.

In an embodiment, the plasma processing chamber 114 (the load 106), may be a medium frequency (MF) or high frequency (HF) plasma chamber, or the like. The plasma processing chamber 114 may be a vacuum chamber. In some embodiments, the plasma processing chamber 114 is configured to operate plasma 112 in a frequency range from about 400 kHz to about 13.56 MHz. Within this frequency range, generally, frequencies from 400 kHz to 3 MHz are classified as Medium Frequencies (MF), and frequencies from 3 MHz to 13.56 MHz are classified as High Frequencies (HF). The plasma processing chamber 114 may comprise any suitable elements such as a process gas input, a chuck 116 (e.g., to hold or support a substrate), or the like. A suitable power delivery method may be utilized to deliver power to the plasma processing chamber 114. For example, in an embodiment, a dielectric window 11o is disposed above the plasma processing chamber 114. A planar coil 108 is disposed above the dielectric window 110. The dielectric window 110 may comprise quartz, or the like. The planar coil 108 serves as an RF antenna which transfers the RF power from the power source 102 across the dielectric window 110 into the plasma processing chamber 114 to generate and sustain the discharge. In other embodiments, other suitable power delivery methods may be utilized to deliver power to the plasma processing chamber 114.

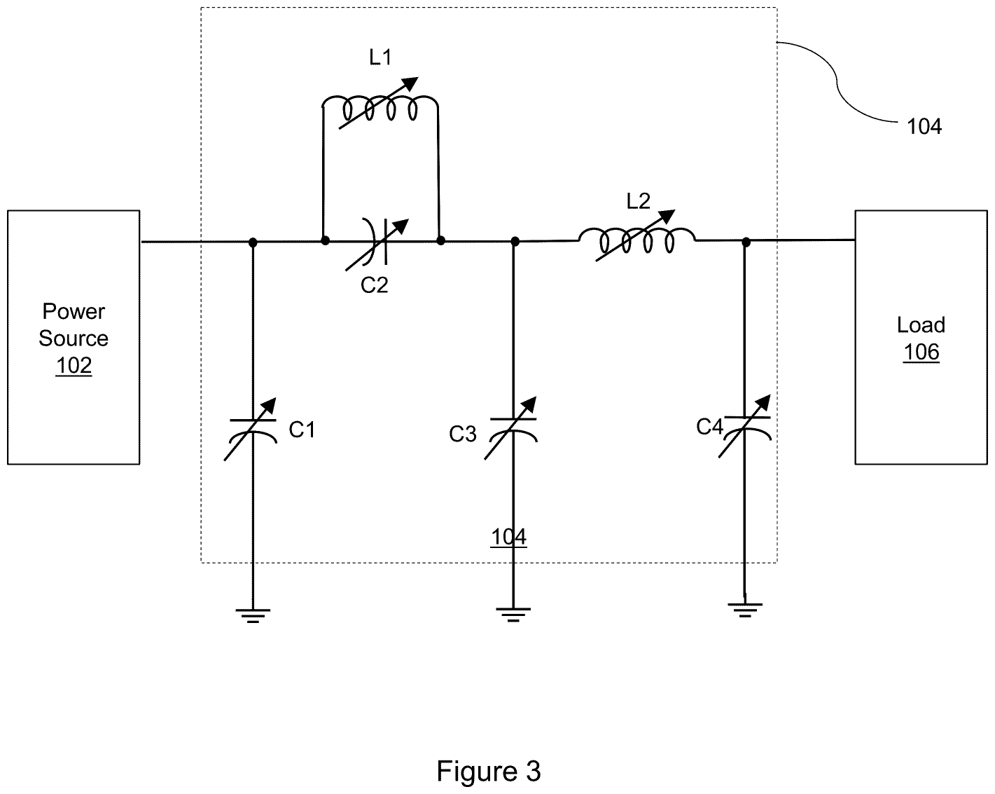

The impedance matching network 104 comprises four adjustable capacitive elements (e.g., variable capacitors), and two adjustable inductive elements (e.g., variable inductors). The impedance matching network 104 comprises two pi-networks in series. One of the adjustable capacitive elements is coupled in parallel with an adjustable inductive element of one of the two pi-networks, wherein the adjustable capacitive element and the adjustable inductive element together form a resonant or tank circuit. In operation, when the operating frequency of the plasma processing chamber 114 varies in the wide operating frequency range (e.g., between about 400 kHz to about 13.56 MHz), the impedance matching network 104 is adjusted so that the impedance of the impedance matching network 104 and the plasma processing chamber 114 equals (e.g., is essentially or substantially equal to) the impedance of the power source 102. The detailed structures of the impedance matching network 104 will be described below with respect to FIGS. 3-8.

FIG. 3 illustrates an implementation of the impedance matching network 104 shown in FIGS. 1-2 in accordance with various embodiments of the present disclosure. The impedance matching network 104 comprises a first pi-network and a second pi-network connected in series between an output of the power source 102 and an input of the load 106. The output of the power source 102 is coupled to the second pi-network through the first pi-network. An additional capacitor is coupled in parallel with an inductor of the first pi-network, wherein the capacitor and the inductor together form a resonant or tank circuit.

The impedance matching network 104 comprises a first capacitor C1, a second capacitor C2, a third capacitor C3, a fourth capacitor C4, a first inductor L1, and a second inductor L2. As can be seen in FIG. 3, the first pi-network of the impedance matching network 104 comprises the first capacitor C1 and the first inductor L1. In addition, the first pi-network shares the third capacitor C3 with the second pi-network. The second pi-network of the impedance matching network 104 comprises the fourth capacitor C4 and the second inductor L2. In addition, the second pi-network shares the third capacitor C3 with the first pi-network. The first capacitor C1, the third capacitor C3, and the fourth capacitor C4 may also be referred to as shunt capacitors. The second capacitor C2 is coupled in parallel with the first inductor L1 of the first pi-network, wherein the second capacitor C2 and the first inductor L1 together form a resonant or tank circuit.

The first capacitor C1 is coupled between an output of the power source 102 and ground. The first inductor L1 is coupled between a common node of the output of the power source 102 and the first capacitor C1, and a common node of the third capacitor C3 and the second inductor L2. The second capacitor C2 is coupled in parallel with the first inductor L1. The third capacitor C3 is coupled between a common node of the first inductor L1 and the second inductor L2, and ground. The second inductor L2 is coupled between a common node of the first inductor L1 and the third capacitor C3, and a common node of the fourth capacitor C4 and the input of the load 106. The fourth capacitor C4 is coupled between the input of the load 106 and ground.

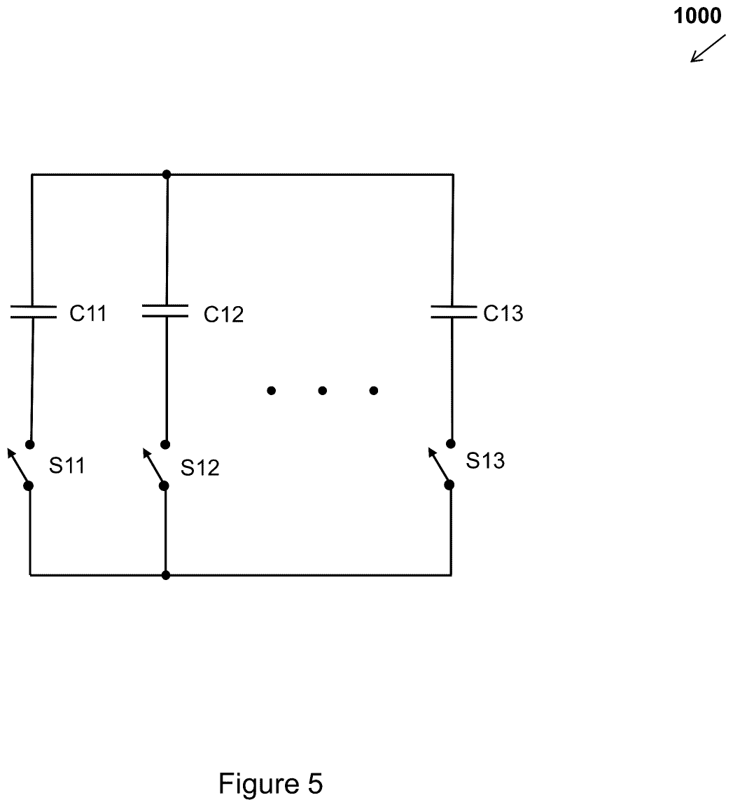

In an embodiment, the first capacitor C1 is implemented as an adjustable capacitor. For example, the first capacitor C1 may comprise a plurality of switch-capacitor networks connected in parallel. Each switch-capacitor network comprises a capacitor and a switch connected in series. By controlling the on and off of the switches of the plurality of switch-capacitor networks, the capacitance of the first capacitor C1 may be varied accordingly. This implementation of this adjustable capacitor will be described further in detail below with respect to FIG. 5. In other embodiments, the first capacitor C1 may have its capacitance changed by mechanical motion. For example, the distance and/or the overlapping area of the two plates of the first capacitor C1 may be adjustable through a suitable mechanical construction. In some embodiments, the first capacitor C1 is able to vary in a range from about 0.003 nF to about 4 nF.

While FIG. 3 illustrates the first capacitor C1 as being implemented as a polarized capacitor, this is merely an example. Advantageous features may be achieved when the first capacitor C1 comprises a polarized capacitor. These may include allowing the first capacitor C1 to achieve a higher capacitance value than would be possible by using other types of capacitors. The first capacitor C1 may be implemented as a non-polarized capacitor depending on different applications and design needs. In some embodiments, the first capacitor C1 may be implemented as any suitable capacitors such as ceramic capacitors, film capacitors, electrolytic capacitors, polymer capacitors, any combinations thereof and the like.

The second capacitor C2, the third capacitor C3, and the fourth capacitor C4 may be similar to the first capacitor C1, and hence the structure and the operating principles of the second capacitor C2, the third capacitor C3, and the fourth capacitor C4 are not discussed in detail herein. The second capacitor C2, the third capacitor C3, and the fourth capacitor C4 are implemented as adjustable capacitors. The second capacitor C2 is able to vary in a range from about 0.300 nF to about 9 nF. The third capacitor C3 is able to vary in a range from about 0.020 nF to about 0.35 nF. The third capacitor C4 is able to vary in a range from about 0.02 nF to about 1.2 nF.

Throughout the description, the first capacitor C1, the third capacitor C3, and the fourth capacitor C4 may be alternatively referred to as a shunt capacitors.

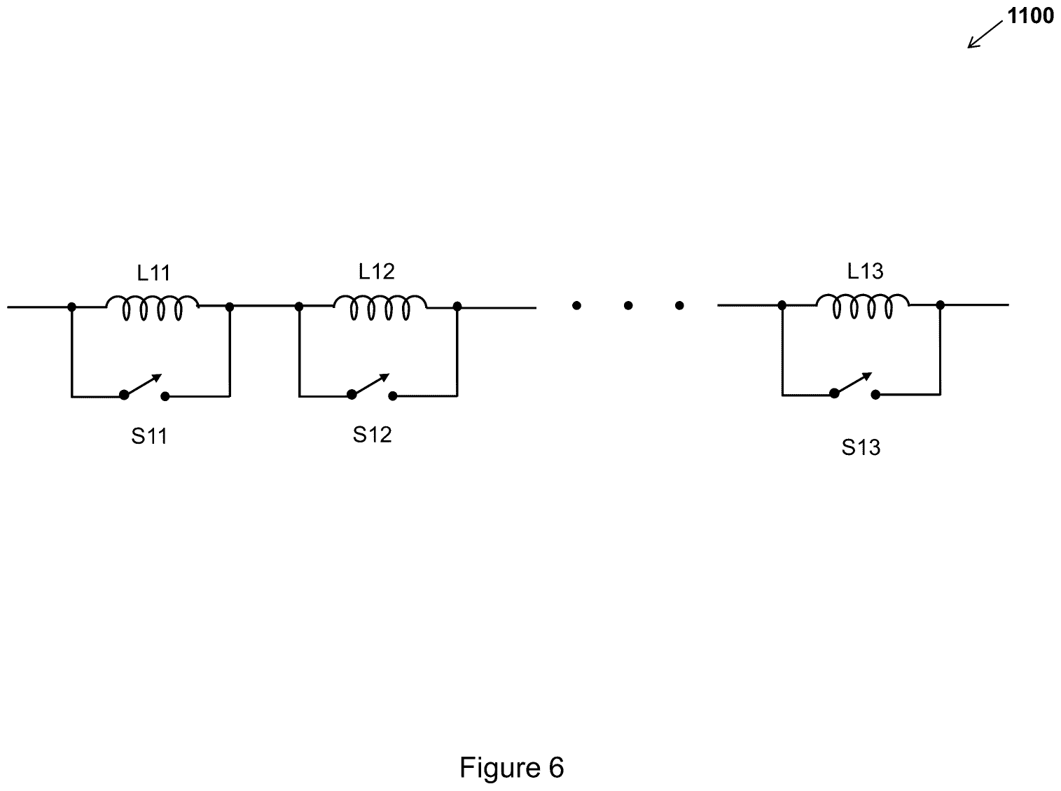

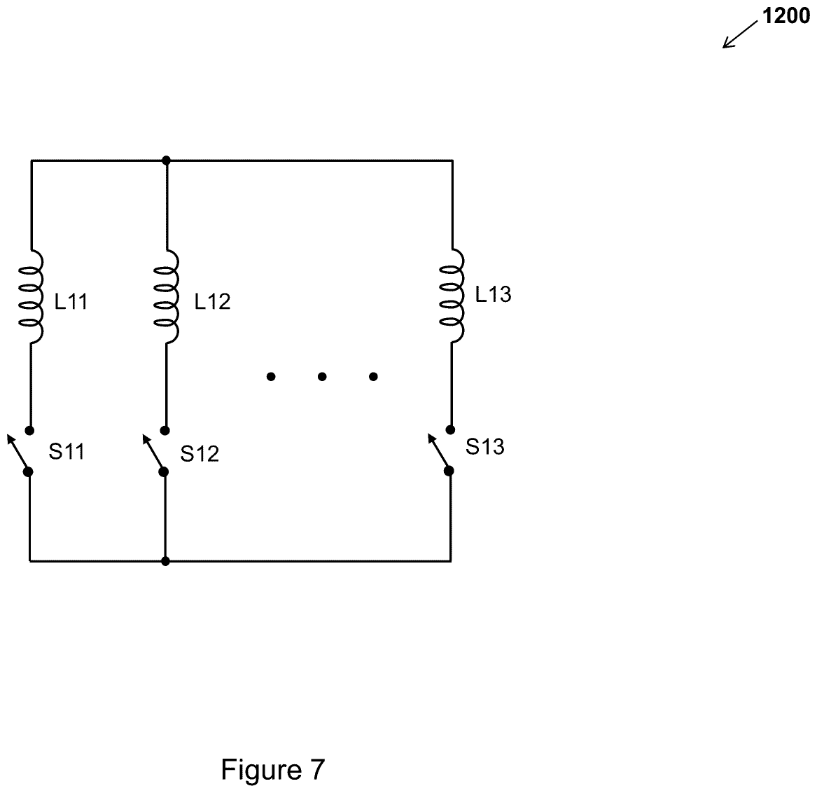

In an embodiment, the first inductor L1 is implemented as an adjustable inductor as shown in FIG. 3. The first inductor L1 may comprise a plurality of switch-inductor networks connected in parallel or in series. In a first implementation of this adjustable inductor, each switch-inductor network comprises an inductor and a switch connected in parallel, and the plurality of switch-inductor networks is connected in series. By controlling the on and off of the switches of the plurality of switch-inductor networks, the inductance of the first inductor L1 varies accordingly. The first implementation of this adjustable inductor will be described further in detail below with respect to FIG. 6. In a second implementation of this adjustable inductor, each switch-inductor network comprises an inductor and a switch connected in series, and the plurality of switch-inductor networks is connected in parallel. By controlling the on and off of the switches of the plurality of switch-inductor networks, the inductance of the first inductor L1 varies accordingly. The second implementation of this adjustable inductor will be described further in detail below with respect to FIG. 7. In a third implementation of this adjustable inductor, the first inductor L1 may have its inductance changed by mechanical motion. For example, the coupling between a magnetic core and a coil of the first inductor L1 may be adjustable through a suitable mechanical construction. In some embodiments, the inductance of the first inductor L1 is in a range from about 5 μH to about 13 μH.

The second inductor L2 may be similar to the first inductor L1, and hence the structure and the operating principles of the second inductor L2 are not discussed in detail herein. The second inductor L2 is implemented as an adjustable inductor. The second inductor L2 is able to vary in a range from about 9 μH to about 10 μH.

In operation, the load 106 is configured to operate in a predetermined frequency range. In some embodiment, the predetermined frequency range is from about 400 kHz to about 13.56 MHz. The power source 102 is configured to provide power for the load 106. The impedance matching network 104 is configured such that, in the predetermined frequency range, the impedance of the impedance matching network 104 and the load 106 equals (e.g., is essentially or substantially equal to) an impedance of the power source 102. More particularly, the load 106 is configured to operate at a first frequency within the predetermined frequency range. Based on the first frequency, the first capacitor C1, the second capacitor C2, the third capacitor C3, the fourth capacitor C4, the first inductor L1, and the second inductor L2 are adjusted individually or in combination such that the impedance of the impedance matching network 104 and the load 106 equals (e.g., is essentially or substantially equal to) the impedance of the power source 102. In this way, the first capacitor C1, the second capacitor C2, the third capacitor C3, the fourth capacitor C4, the first inductor L1, and the second inductor L2 are dynamically adjusted such that the impedance of the impedance matching network 104 and the load 106 equals (e.g., is essentially or substantially equal to) the impedance of the power source 102.

The operation of the impedance matching network 104 can be described in context of a smith chart. Impedance matching requires normalizing the load impedance (e.g., an impedance of the load 106) and the source impedance (e.g., an impedance of the power source 102) to a desired impedance. The normalized impedance of the load 106 can plotted as a first point on the smith chart, and the normalized impedance of the power source 102 can be plotted as a second point on the smith chart. Using the smith chart, the first point and the second point can be compared, and measuring the required shift in the reactance values and resistance values between the first point and the second point can determine what type of components are needed in a matching network, and how large the values of these components are. The impedance matching network 104 may operate in a similar manner and compares the normalized impedance of the load 106 to the normalized impedance of the power source 102. Because the impedance matching network 104 comprises 4 adjustable capacitors (e.g., the first capacitor C1, the second capacitor C2, the third capacitor C3, and the fourth capacitor C4) and 2 adjustable inductors (e.g., the first inductor L1 and the second inductor L2), and since the number of these components is fixed, the impedance matching network 104 will only vary the values of these components till the first point and the second point overlap on the smith chart, and the impedance of the impedance matching network 104 and the load 106 equals (e.g., is essentially or substantially equal to) the impedance of the power source 102. Because the impedance matching network 104 comprises 2 adjustable inductors, the impedance matching network 104 is able to utilize an inductive region of the smith chart (e.g., by allowing increasing series inductance and decreasing series inductance) that was not previously able to be utilized by previous impedance matching networks that only comprised capacitors (e.g., the high frequency impedance matching network described previously).

The impedance matching network 104 is able to isolate the power source 102 from any higher frequencies that may be present at the load 106 (plasma processing chamber 114) that are above the frequency range that the broadband impedance matching network 104 is designed for. The impedance matching network 104 acts as a low pass filter to prevent these higher frequency signals from travelling to the power source 102 and therefore eliminates any detrimental effects that this may cause.

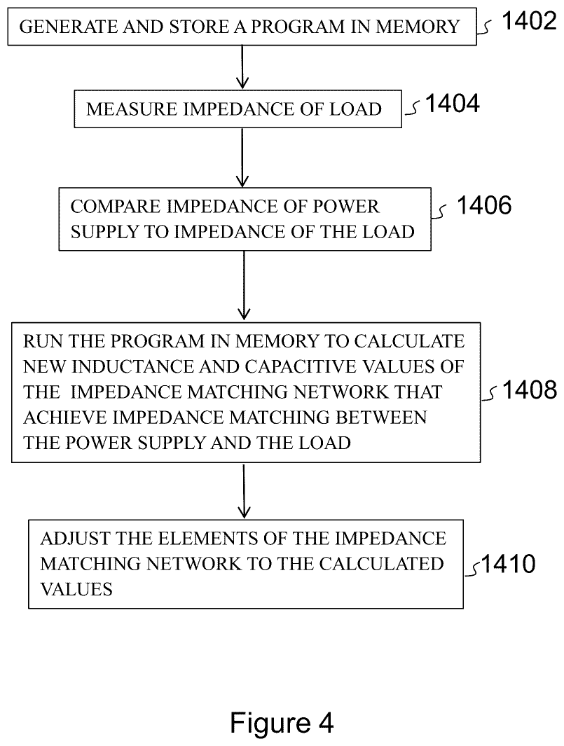

FIG. 4 shows a flow chart of a method used for varying the values of the 4 adjustable capacitors (e.g., the first capacitor C1, the second capacitor C2, the third capacitor C3, and the fourth capacitor C4) and the 2 adjustable inductors (e.g., the first inductor L1 and the second inductor L2) of the impedance matching network 104 shown in FIGS. 1-3, in order to achieve impedance matching. At step 1402, a program is generated and stored in a memory of an associated controller that is coupled to the impedance matching network 104. At step 1404, the impedance of the load 106 is measured by using a V/I probe, or the like. At step 1406, the measured impedance of the load 106 is compared to the impedance of the power source 102. At step 1408, the program stored in memory is executed to calculate capacitance values for the first capacitor C1, the second capacitor C2, the third capacitor C3, and the fourth capacitor C4, as well as inductance values for the first inductor L1 and the second inductor L2, that would allow the impedance of the impedance matching network 104 and the load 106 to equal (e.g., is essentially or substantially equal) the impedance of the power source 102. At step 1410, one or more of the first capacitor C1, the second capacitor C2, the third capacitor C3, the fourth capacitor C4, the first inductor L1, and the second inductor L2 are adjusted so that each of the elements match the values that were calculated at step 1408.

Advantages can be achieved by having the impedance matching network 104 that comprises four adjustable capacitive elements (e.g., the first capacitor C1, the second capacitor C2, the third capacitor C3, and the fourth capacitor C4), and two adjustable inductive elements (e.g., the first inductor L1 and the second inductor L2). These elements of the impedance matching network 104 are arranged to form a first pi-network and a second pi-network in series, with the output of the power source 102 being coupled to the second pi-network through the first pi-network. One of the adjustable capacitive elements (e.g., the second capacitor C2) is coupled in parallel with an adjustable inductive element (e.g., the first inductor L1) of the first pi-network. One advantage includes allowing for an increase in the range of the impedance variation of the impedance matching network 104. In the conventional L-shaped impedance matching network, only two capacitive elements are available for adjusting the impedance of the L-shaped impedance matching network. The capacitive elements have a limited impedance variation range. By employing the impedance matching network 104 into the plasma processing system 100 as shown in FIG. 3, the impedance variation range can be further extended. For example, the conventional L-shaped impedance matching network can only provide high frequency impedance matching when the load 106 operates in a limited frequency range (e.g., at high frequencies from about 11 MHz to 15 MHz). By contrast, the impedance matching network 104 can provide broadband impedance matching when the load 106 operates in a wide frequency range (e.g., covering a range of medium to high frequencies from a lower frequency limit of about 400 kHz to an upper frequency limit of about 13.56 MHz). A second advantage includes allowing for the isolation of the power source 102 from any higher frequencies that may be present at the load 106 (plasma processing chamber 114) that are above the frequency range (e.g., higher than the upper frequency limit 13.56 MHz) that the broadband impedance matching network 104 is designed for. For example, certain components in the plasma processing chamber 114 may need to be supplied with power using higher frequencies than the frequency range (e.g., higher than 13.56 MHz) that the broadband impedance matching network 104 is designed for. The impedance matching network 104 acts as a filter or block to prevent these higher frequency signals (e.g., above 13.56 MHz) from travelling to the power source 102 and therefore eliminates any detrimental effects that this may cause.

As a first example of the operation of the broadband impedance matching network 104, when the load 106 is configured to operate at a frequency of 400 kHz, the adjustable elements of the impedance matching network 104 are adjusted individually or in combination such that the impedance of the impedance matching network 104 and the load 106 equals (e.g., is essentially or substantially equal to) the impedance of the power source 102. Based on the frequency of the load 106 being 400 kHz, the first capacitor C1 may have a capacitance value of 1 nF, the second capacitor C2 may have a capacitance value of 8.3 nF, the third capacitor C3 may have a capacitance value of 0.025 nF, the fourth capacitor C4 may have a capacitance value of 1.1 nF, the first inductor L1 may have an inductance value of 12.7 PH, and the second inductor L2 may have an inductance value of 9.5 μH. These are just example values of the adjustable elements of the impedance matching network 104 such that the impedance of the impedance matching network 104 and the load 106 equals (e.g., is essentially or substantially equal to) the impedance of the power source 102. However, other combinations of values of the adjustable elements of the impedance matching network 104 are also possible at the load frequency of 400 kHz that also result in the impedance of the impedance matching network 104 and the load 106 being equal (e.g., is essentially or substantially equal) to the impedance of the power source 102. Additionally, the impedance matching network 104 acts as a filter or block to prevent higher frequencies that may be present at the load 106 that are above 13.56 MHz (the upper frequency limit that the broadband impedance matching network 104 is designed for) from travelling to the power source 102.

As a second example of the operation of the broadband impedance matching network 104, when the load 106 is configured to operate at a frequency of 1 MHz, the adjustable elements of the impedance matching network 104 are adjusted individually or in combination such that the impedance of the impedance matching network 104 and the load 106 equals (e.g., is essentially or substantially equal to) the impedance of the power source 102. Based on the frequency of the load 106 being 1 MHz, the first capacitor C1 may have a capacitance value of 1 nF, the second capacitor C2 may have a capacitance value of 2.15 nF, the third capacitor C3 may have a capacitance value of 0.327 nF, the fourth capacitor C4 may have a capacitance value of 0.023 nF, the first inductor L1 may have an inductance value of 6 PH, and the second inductor L2 may have an inductance value of 9.5 μH. These are just example values of the adjustable elements of the impedance matching network 104 such that the impedance of the impedance matching network 104 and the load 106 equals (e.g., is essentially or substantially equal to) the impedance of the power source 102. However, other combinations of values of the adjustable elements of the impedance matching network 104 are also possible at the load frequency of 1 MHz that also result in the impedance of the impedance matching network 104 and the load 106 being equal (e.g., is essentially or substantially equal) to the impedance of the power source 102. Additionally, the impedance matching network 104 acts as a filter or block to prevent higher frequencies that may be present at the load 106 that are above 13.56 MHz (the upper frequency limit that the broadband impedance matching network 104 is designed for) from travelling to the power source 102.

As a third example of the operation of the broadband impedance matching network 104, when the load 106 is configured to operate at frequencies of either 1 MHz or 13.56 MHz, the adjustable elements of the impedance matching network 104 are adjusted individually or in combination such that the impedance of the impedance matching network 104 and the load 106 equals (e.g., is essentially or substantially equal to) the impedance of the power source 102. Based on the frequency of the load 106 being either 1 MHz or 13.56 MHz, the first capacitor C1 may have a capacitance value of 1 nF, the second capacitor C2 may have a capacitance value of 1.6 nF, the third capacitor C3 may have a capacitance value of 0.233 nF, the fourth capacitor C4 may have a capacitance value of 0.027 nF, the first inductor L1 may have an inductance value of 8.7 μH, and the second inductor L2 may have an inductance value of 9.5 PH. These are just example values of the adjustable elements of the impedance matching network 104 when the load 106 is configured to operate at either 1 MHz or 13.56 MHz, such that the impedance of the impedance matching network 104 and the load 106 equals (e.g., is essentially or substantially equal to) the impedance of the power source 102. However, other combinations of values of the adjustable elements of the impedance matching network 104 are also possible at each of the load frequencies of 1 MHz and 13.56 MHz that also result in the impedance of the impedance matching network 104 and the load 106 being equal (e.g., is essentially or substantially equal) to the impedance of the power source 102. Additionally, the impedance matching network 104 acts as a filter or block to prevent higher frequencies that may be present at the load 106 that are above 13.56 MHz (the upper frequency limit that the broadband impedance matching network 104 is designed for) from travelling to the power source 102.

As a fourth example of the operation of the broadband impedance matching network 104, when the load 106 is configured to operate at a frequency of 2 MHz, the adjustable elements of the impedance matching network 104 are adjusted individually or in combination such that the impedance of the impedance matching network 104 and the load 106 equals (e.g., is essentially or substantially equal to) the impedance of the power source 102. Based on the frequency of the load 106 being 2 MHz, the first capacitor C1 may have a capacitance value of 1 nF, the second capacitor C2 may have a capacitance value of 0.348 nF, the third capacitor C3 may have a capacitance value of 0.036 nF, the fourth capacitor C4 may have a capacitance value of 0.027 nF, the first inductor L1 may have an inductance value of 8.7 PH, and the second inductor L2 may have an inductance value of 9.5 μH. These are just example values of the adjustable elements of the impedance matching network 104 such that the impedance of the impedance matching network 104 and the load 106 equals (e.g., is essentially or substantially equal to) the impedance of the power source 102. However, other combinations of values of the adjustable elements of the impedance matching network 104 are also possible at the load frequency of 2 MHz that also result in the impedance of the impedance matching network 104 and the load 106 being equal (e.g., is essentially or substantially equal) to the impedance of the power source 102. Additionally, the impedance matching network 104 acts as a filter or block to prevent higher frequencies that may be present at the load 106 that are above 13.56 MHz (the upper frequency limit that the broadband impedance matching network 104 is designed for) from travelling to the power source 102.

As a fifth example of the operation of the broadband impedance matching network 104, when the load 106 is configured to operate at a frequency of 13.56 MHz, the adjustable elements of the impedance matching network 104 are adjusted individually or in combination such that the impedance of the impedance matching network 104 and the load 106 equals (e.g., is essentially or substantially equal to) the impedance of the power source 102. Based on the frequency of the load 106 being 13.56 MHz, the first capacitor C1 may have a capacitance value of 1 nF, the second capacitor C2 may have a capacitance value of 1.191 nF, the third capacitor C3 may have a capacitance value of 0.225 nF, the fourth capacitor C4 may have a capacitance value of 0.027 nF, the first inductor L1 may have an inductance value of 8.7 PH, and the second inductor L2 may have an inductance value of 9.5 μH. These are just example values of the adjustable elements of the impedance matching network 104 such that the impedance of the impedance matching network 104 and the load 106 equals (e.g., is essentially or substantially equal to) the impedance of the power source 102. However, other combinations of values of the adjustable elements of the impedance matching network 104 are also possible at the load frequency of 13.56 MHz that also result in the impedance of the impedance matching network 104 and the load 106 being equal (e.g., is essentially or substantially equal) to the impedance of the power source 102. Additionally, the impedance matching network 104 acts as a filter or block to prevent higher frequencies that may be present at the load 106 that are above 13.56 MHz (the upper frequency limit that the broadband impedance matching network 104 is designed for) from travelling to the power source 102.

FIG. 5 illustrates an implementation of an adjustable capacitor 1000 of the impedance matching network 104 shown in FIG. 1 in accordance with various embodiments of the present disclosure. This implementation of the adjustable capacitor 1000 may be used for one or more of the first capacitor C1, the second capacitor C2, the third capacitor C3, or the fourth capacitor C4, and may comprise a plurality of switch-capacitor networks connected in parallel. As shown in FIG. 5, a first switch-capacitor network comprises a capacitor C11 and a switch S11 connected in series. A second switch-capacitor network comprises a capacitor C12 and a switch S12 connected in series. A third switch-capacitor network comprises a capacitor C13 and a switch S13 connected in series. There may be a predetermined number of switch-capacitor networks connected between the second switch-capacitor network and the third switch-capacitor network. By controlling the on and off of the switches of the plurality of switch-capacitor networks, the capacitance of the adjustable capacitor 1000 varies accordingly. It should be noted the implementations of the adjustable capacitor 1000 shown in FIG. 5 is merely an exemplary implementation and is not meant to limit the current embodiments. Other suitable implementations of the adjustable capacitor 1000 may alternatively be used for any of the first capacitor C1, the second capacitor C2, the third capacitor C3, or the fourth capacitor C4.

FIG. 6 illustrates a first implementation of an adjustable inductor 1100 of the impedance matching network 104 shown in FIG. 1 in accordance with various embodiments of the present disclosure. This implementation of the adjustable inductor 1100 may be used for one or both of the first inductor L1 and the second inductor L2, and may comprise a plurality of switch-inductor networks connected in series. As shown in FIG. 6, a first switch-inductor network comprises an inductor L11 and a switch S11 connected in parallel. A second switch-inductor network comprises an inductor L12 and a switch S12 connected in parallel. A third switch-inductor network comprises an inductor L13 and a switch S13 connected in parallel. There may be a predetermined number of switch-inductor networks connected between the second switch-inductor network and the third switch-inductor network. By controlling the on and off of the switches of the plurality of switch-inductor networks, the inductance of the adjustable inductor 1100 varies accordingly.

FIG. 7 illustrates a second implementation of an adjustable inductor 1200 of the impedance matching network 104 shown in FIG. 1 in accordance with various embodiments of the present disclosure. This implementation of the adjustable inductor 1200 may be used for one or both of the first inductor L1 and the second inductor L2, and may comprise a plurality of switch-inductor networks connected in parallel. As shown in FIG. 7, a first switch-inductor network comprises an inductor L11 and a switch S11 connected in series. A second switch-inductor network comprises an inductor L12 and a switch S12 connected in series. A third switch-inductor network comprises an inductor L13 and a switch S13 connected in series. There may be a predetermined number of switch-inductor networks connected between the second switch-inductor network and the third switch-inductor network. By controlling the on and off of the switches of the plurality of switch-inductor networks, the inductance of the adjustable inductor 1200 varies accordingly. It should be noted the implementations of the adjustable inductors 1100 and 1200 shown in FIGS. 6-7 are merely exemplary implementations and are not meant to limit the current embodiments. Other suitable implementations of the adjustable inductor 1100 and the adjustable inductor 1200, such as deformation of a coil inductor through stretching, compressing, twisting, any combinations thereof, may alternatively be used.

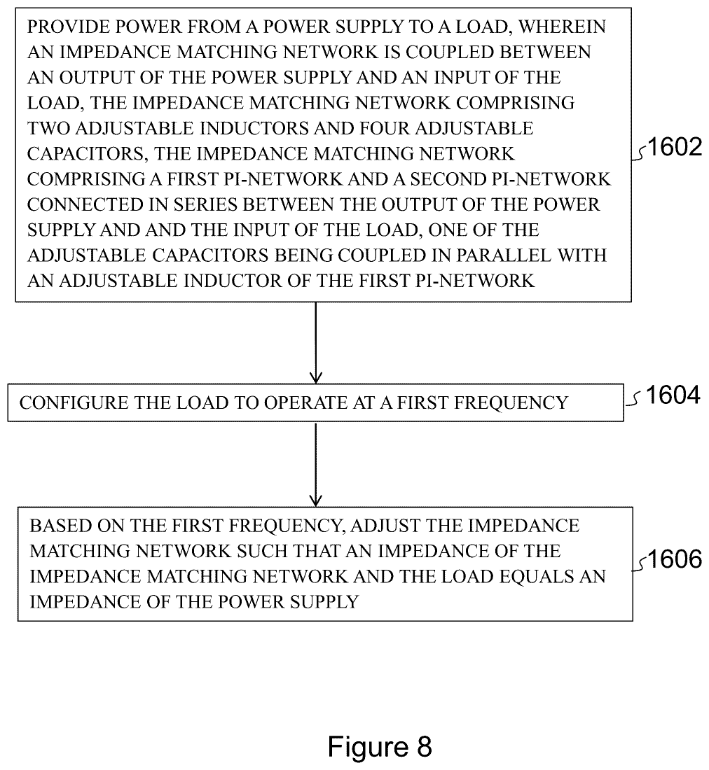

FIG. 8 illustrates a flow chart of a method for controlling the impedance matching network shown in FIG. 1 in accordance with various embodiments of the present disclosure. This flowchart shown in FIG. 8 is merely an example, which should not unduly limit the scope of the claims. One of ordinary skill in the art would recognize many variations, alternatives, and modifications. For example, various steps illustrated in FIG. 8 may be added, removed, replaced, rearranged and repeated.

A power source is coupled to a load through an impedance matching network. The power source is a high frequency RF power source. The load is a plasma chamber. The plasma chamber may operate in a wide frequency range. The impedance matching network comprises four adjustable capacitors and two adjustable inductors as shown in FIGS. 3-7.

At step 1602, power is provided from the power source to the load. The impedance matching network is coupled between an output of the power source and an input of the load. The impedance matching network comprises a first pi-network and a second pi-network connected in series between an output of the power source and an input of the load. The output of the power source is coupled to the second pi-network through the first pi-network. An additional adjustable capacitor is coupled in parallel with an adjustable inductor of the first pi-network, wherein the adjustable capacitor and the adjustable inductor together form a resonant or tank circuit. The impedance matching network comprises two adjustable inductors and four adjustable capacitors in total.

At step 1604, the load (e.g., the plasma chamber) is configured to operate at a first frequency (e.g., one predetermined frequency in a range from about 400 kHz to about 13.56 MHz).

At step 1606, based on the first frequency, the impedance matching network is adjusted such that an impedance of the impedance matching network and the load equals (e.g., is essentially or substantially equal to) an impedance of the power source.

Example embodiments of the invention are described below. Other embodiments can also be understood from the entirety of the specification as well as the claims filed herein.

Example 1. A matching circuit for a plasma tool includes an impedance matching network configured to be coupled between a power supply and a plasma chamber. The plasma chamber is configured to operate a plasma in a predetermined frequency range, the power supply being configured to provide power for the plasma chamber. The impedance matching network includes a first pi-network and a second pi-network in series coupled between an input of the plasma chamber and an output of the power supply. The impedance matching network is configured such that, during operation of the plasma chamber in the predetermined frequency range, an impedance of the impedance matching network and the plasma chamber equals an impedance of the power supply.

Example 2. The matching circuit of claim 1, where the plasma chamber is configured to operate the plasma in the predetermined frequency range that extends from a lower frequency of about 400 kHz to an upper frequency of about 13.56 MHz.

Example 3. The matching circuit of example 2, where the impedance matching network is configured to isolate the power supply from any frequencies that are higher than the upper frequency that are present at the plasma chamber.

Example 4. The matching circuit of any one of examples 1-3, where the output of the power supply is coupled to the second pi-network through the first pi-network.

Example 5. The matching circuit of example 4, where the first pi-network includes: a first adjustable capacitor coupled between the output of the power supply and ground; a first adjustable inductor coupled between a common node of the output of the power supply and the first adjustable capacitor, and a common node of a second adjustable capacitor and a second adjustable inductor; and the second adjustable capacitor coupled between a common node of the first adjustable inductor and the second adjustable inductor, and ground.

Example 6. The matching circuit of example 5, where the second pi-network includes: the second adjustable capacitor, where the second adjustable capacitor is shared by both the first pi-network and the second pi-network; the second adjustable inductor coupled between a common node of the first adjustable inductor and the second adjustable capacitor, and a common node of a third adjustable capacitor and the input of the plasma chamber; and the third adjustable capacitor coupled between the input of the plasma chamber and ground.

Example 7. The matching circuit of example 6, where the impedance matching network further includes a fourth adjustable capacitor coupled in parallel with the first adjustable inductor.

Example 8. The matching circuit of example 7, where the first adjustable capacitor, the second adjustable capacitor, and the third adjustable capacitor are shunt capacitors.

Example 9. A method includes providing power from a power supply to a plasma chamber, an impedance matching network being coupled between an output of the power supply and an input of the plasma chamber. The impedance matching network includes a first pi-network and a second pi-network connected in series. The impedance matching network includes a combined total of six adjustable capacitive elements and adjustable inductive elements. The method includes configuring the plasma chamber to operate at a first frequency within a predetermined frequency range, the predetermined frequency range extending from a second frequency to a third frequency, the third frequency being higher than the second frequency; and based on the first frequency. The method includes adjusting the impedance matching network such that an impedance of the impedance matching network and the plasma chamber equals an impedance of the power supply.

Example 10. The method of example 9, further including: isolating the power supply from any frequencies that are present at the plasma chamber that are higher than the third frequency using the impedance matching network.

Example 11. The method of example 10, further including: configuring the plasma chamber to operate in a fourth frequency in the predetermined frequency range; and based on the fourth frequency, adjusting the impedance matching network such that in the predetermined frequency range, the impedance of the impedance matching network and the plasma chamber equals the impedance of the power supply.

Example 12. The method of example 10, where the first pi-network includes: a first adjustable capacitor coupled between the output of the power supply and ground; a first adjustable inductor coupled between a common node of the output of the power supply and the first adjustable capacitor, and a common node of a second adjustable capacitor and a second adjustable inductor; and the second adjustable capacitor coupled between a common node of the first adjustable inductor and the second adjustable inductor, and ground.

Example 13. The method of example 12, where the second pi-network includes: the second adjustable capacitor, where the second adjustable capacitor is shared by both the first pi-network and the second pi-network; the second adjustable inductor coupled between a common node of the first adjustable inductor and the second adjustable capacitor, and a common node of a third adjustable capacitor and the input of the plasma chamber; and the third adjustable capacitor coupled between the input of the plasma chamber and ground.

Example 14. The method of example 13, where the impedance matching network further includes: a fourth adjustable capacitor coupled in parallel with the first adjustable inductor.

Example 15. The method of example 14, further including: dynamically adjusting the first adjustable capacitor, the second adjustable capacitor, the third adjustable capacitor, the fourth adjustable capacitor, the first adjustable inductor, and the second adjustable inductor such that the impedance of the impedance matching network and the plasma chamber equals the impedance of the power supply.

Example 16. A system includes a plasma chamber coupled to a power source; and an impedance matching network coupled between an output of the power source and an input of the plasma chamber, where the impedance matching network is configured such that, in a predetermined frequency range, an impedance of the impedance matching network and the plasma chamber is equal to an impedance of the power source, where the impedance matching network includes: a first pi-network including a first adjustable capacitor, a second adjustable capacitor and a first adjustable inductor; and a third adjustable capacitor coupled in parallel with the first adjustable inductor.

Example 17. The system of example 16, where the first adjustable capacitor is coupled between the output of the power source and ground, where the second adjustable capacitor is coupled between a common node of the first adjustable inductor and a second adjustable inductor, and ground, and where the first adjustable inductor is coupled between a common node of the output of the power source and the first adjustable capacitor, and a common node of the second adjustable capacitor and the second adjustable inductor.

Example 18. The system of example 17, where the impedance matching network further includes: a second pi-network connected in series with the first pi-network, the second pi-network including: the second adjustable capacitor, where the second adjustable capacitor is shared by both the first pi-network and the second pi-network; the second adjustable inductor coupled between a common node of the first adjustable inductor and the second adjustable capacitor, and a common node of a fourth adjustable capacitor and the input of the plasma chamber; and the fourth adjustable capacitor coupled between the input of the plasma chamber and ground.

Example 19. The system of example 16, where the plasma chamber is configured to operate a plasma within the plasma chamber in the predetermined frequency range from about 400 kHz to about 13.56 MHz.

Example 20. The system of example 19, where the impedance matching network is configured to act as a filter and prevent frequencies that are present at the plasma chamber that are higher than the predetermined frequency range from traveling to the power source.

Although embodiments of the present disclosure and its advantages have been described in detail, it should be understood that various changes, substitutions and alterations can be made herein without departing from the spirit and scope of the disclosure as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A matching circuit for a plasma tool comprising:
an impedance matching network configured to be coupled between a power supply and a plasma chamber, the plasma chamber being configured to operate a plasma in a predetermined frequency range, the power supply being configured to provide power for the plasma chamber, the impedance matching network comprising a first pi-network and a second pi-network in series coupled between an input of the plasma chamber and an output of the power supply, and the impedance matching network being configured such that, during operation of the plasma chamber in the predetermined frequency range, an impedance of the impedance matching network and the plasma chamber equals an impedance of the power supply.

2. The matching circuit of claim 1, wherein the plasma chamber is configured to operate the plasma in the predetermined frequency range that extends from a lower frequency of about 400 kHz to an upper frequency of about 13.56 MHz.

3. The matching circuit of claim 2, wherein the impedance matching network is configured to isolate the power supply from any frequencies that are higher than the upper frequency that are present at the plasma chamber.

4. The matching circuit of claim 1, wherein the output of the power supply is coupled to the second pi-network through the first pi-network.

5. The matching circuit of claim 4, wherein the first pi-network comprises:
a first adjustable capacitor coupled between the output of the power supply and ground;
a first adjustable inductor coupled between a common node of the output of the power supply and the first adjustable capacitor, and a common node of a second adjustable capacitor and a second adjustable inductor; and
the second adjustable capacitor coupled between a common node of the first adjustable inductor and the second adjustable inductor, and ground.

6. The matching circuit of claim 5, wherein the second pi-network comprises:
the second adjustable capacitor, wherein the second adjustable capacitor is shared by both the first pi-network and the second pi-network;
the second adjustable inductor coupled between a common node of the first adjustable inductor and the second adjustable capacitor, and a common node of a third adjustable capacitor and the input of the plasma chamber; and
the third adjustable capacitor coupled between the input of the plasma chamber and ground.

7. The matching circuit of claim 6, wherein the impedance matching network further comprises a fourth adjustable capacitor coupled in parallel with the first adjustable inductor.

8. The matching circuit of claim 7, wherein the first adjustable capacitor, the second adjustable capacitor, and the third adjustable capacitor are shunt capacitors.

9. A method comprising:
providing power from a power supply to a plasma chamber, an impedance matching network being coupled between an output of the power supply and an input of the plasma chamber, the impedance matching network comprising a first pi-network and a second pi-network connected in series, and the impedance matching network comprising a combined total of six adjustable capacitive elements and adjustable inductive elements;
configuring the plasma chamber to operate at a first frequency within a predetermined frequency range, the predetermined frequency range extending from a second frequency to a third frequency, the third frequency being higher than the second frequency; and
based on the first frequency, adjusting the impedance matching network such that an impedance of the impedance matching network and the plasma chamber equals an impedance of the power supply.

10. The method of claim 9, further comprising:
isolating the power supply from any frequencies that are present at the plasma chamber that are higher than the third frequency using the impedance matching network.

11. The method of claim 10, further comprising:
configuring the plasma chamber to operate in a fourth frequency in the predetermined frequency range; and
based on the fourth frequency, adjusting the impedance matching network such that in the predetermined frequency range, the impedance of the impedance matching network and the plasma chamber equals the impedance of the power supply.

12. The method of claim 10, wherein the first pi-network comprises:
a first adjustable capacitor coupled between the output of the power supply and ground;
a first adjustable inductor coupled between a common node of the output of the power supply and the first adjustable capacitor, and a common node of a second adjustable capacitor and a second adjustable inductor; and
the second adjustable capacitor coupled between a common node of the first adjustable inductor and the second adjustable inductor, and ground.

13. The method of claim 12, wherein the second pi-network comprises:
the second adjustable capacitor, wherein the second adjustable capacitor is shared by both the first pi-network and the second pi-network;
the second adjustable inductor coupled between a common node of the first adjustable inductor and the second adjustable capacitor, and a common node of a third adjustable capacitor and the input of the plasma chamber; and
the third adjustable capacitor coupled between the input of the plasma chamber and ground.

14. The method of claim 13, wherein the impedance matching network further comprises:
a fourth adjustable capacitor coupled in parallel with the first adjustable inductor.

15. The method of claim 14, further comprising:
dynamically adjusting the first adjustable capacitor, the second adjustable capacitor, the third adjustable capacitor, the fourth adjustable capacitor, the first adjustable inductor, and the second adjustable inductor such that the impedance of the impedance matching network and the plasma chamber equals the impedance of the power supply.

16. A system comprising:
a plasma chamber coupled to a power source; and
an impedance matching network coupled between an output of the power source and an input of the plasma chamber, wherein the impedance matching network is configured such that, in a predetermined frequency range, an impedance of the impedance matching network and the plasma chamber is equal to an impedance of the power source, wherein the impedance matching network comprises:
a first pi-network comprising a first adjustable capacitor, a second adjustable capacitor and a first adjustable inductor; and
a third adjustable capacitor coupled in parallel with the first adjustable inductor.

17. The system of claim 16, wherein the first adjustable capacitor is coupled between the output of the power source and ground, wherein the second adjustable capacitor is coupled between a common node of the first adjustable inductor and a second adjustable inductor, and ground, and wherein the first adjustable inductor is coupled between a common node of the output of the power source and the first adjustable capacitor, and a common node of the second adjustable capacitor and the second adjustable inductor.

18. The system of claim 17, wherein the impedance matching network further comprises:
a second pi-network connected in series with the first pi-network, the second pi-network comprising:
the second adjustable capacitor, wherein the second adjustable capacitor is shared by both the first pi-network and the second pi-network;
the second adjustable inductor coupled between a common node of the first adjustable inductor and the second adjustable capacitor, and a common node of a fourth adjustable capacitor and the input of the plasma chamber; and
the fourth adjustable capacitor coupled between the input of the plasma chamber and ground.

19. The system of claim 16, wherein the plasma chamber is configured to operate a plasma within the plasma chamber in the predetermined frequency range from about 400 kHz to about 13.56 MHz.

20. The system of claim 19, wherein the impedance matching network is configured to act as a filter and prevent frequencies that are present at the plasma chamber that are higher than the predetermined frequency range from traveling to the power source
